(19) United States
(12) Patent Application Publication
(10) Pub. No.: US 2010/0186815 A1
(43) Pub. Date: Jul. 29, 2010

(54) Photovoltaic Device With Improved Crystal Orientation

(75) Inventors: Yu Yang, Perrysburg, OH (US); Boil Pashmakov, Troy, MI (US); Zhibo Zhao, Novi, MI (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/687,697

(22) Filed: Jan. 14, 2010

Related U.S. Application Data
(60) Provisional application No. 61/148,276, filed on Jan. 29, 2009.

(51) Int. Cl. H01L 31/0224; H01L 31/18; H01L 31/0296

(52) U.S. Cl. 136/256; 438/84; 257/E31.126; 257/E31.015

(57) ABSTRACT

A photovoltaic device can include a semiconductor absorber layer with improved cadmium telluride orientation.

### CLAIM FOR PRIORITY

This application claims priority under 35 U.S.C. §119(e) to Provisional U.S. Patent Application Ser. No. 61/148,276 filed on Jan. 29, 2009, which is hereby incorporated by reference.

### TECHNICAL FIELD

The present invention relates to photovoltaic devices and methods of production.

### BACKGROUND

Photovoltaic devices include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity.

Photovoltaic devices can also contain one or more transparent conductive oxide layers, which are also often conductors of electrical charge.

### DESCRIPTION OF DRAWINGS

FIG. 1 is a schematic of a photovoltaic device having multiple layers.

FIG. 2 is a schematic of a photovoltaic device having multiple layers.

FIG. 3 is a schematic of a photovoltaic device having multiple layers.

FIG. 4 is a schematic of a photovoltaic device having multiple layers.

FIG. 5 depicts results of a microstructure analysis of photovoltaic devices having multiple layers.

### DETAILED DESCRIPTION

A photovoltaic device containing a cadmium telluride material having an improved crystal orientation can result in a photovoltaic device with improved carrier mobility and enhanced device performance.

A photovoltaic device can include a transparent conductive oxide layer adjacent to a substrate and layers of semiconductor material. The layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current which, combined with the resulting voltage from the electric field, creates power. The result is the conversion of photon energy into electric power.

The performance of the photovoltaic device can be enhanced by using a cadmium telluride layer with an improved orientation for the p-type absorber layer. The improved orientation of the cadmium telluride can result in larger grain size, the result of which is a higher carrier mobility.

The photovoltaic device can include a barrier layer positioned between the substrate and the transparent conductive oxide layer to prohibit the diffusion of sodium, which is common when using soda-lime glass substrates, and can lead to device degradation and delamination. This barrier layer can be part of a transparent conductive oxide stack. The device can include a top layer buffer adjacent to the transparent conductive oxide layer, which can also be part of the transparent conductive oxide stack. The device can include a back contact adjacent to the semiconductor bi-layer. The device can include a back support adjacent to the back contact to protect the photovoltaic device from external elements.

A method of making a photovoltaic device can include depositing a semiconductor window layer adjacent to a transparent conductive oxide layer, and depositing a semiconductor absorber layer adjacent to the semiconductor window layer. To achieve enhanced performance, a cadmium telluride layer with improved crystal orientation can be used for the semiconductor absorber layer. To prevent the diffusion of sodium, the method can include depositing a barrier layer between the transparent conductive oxide layer and the substrate to form a transparent conductive oxide stack. A top layer buffer may be deposited adjacent to the transparent conductive oxide layer to form a transparent conductive oxide stack. The method can include annealing the transparent conductive oxide stack. For example, the transparent conductive oxide stack may be heated at any suitable temperature range, for any suitable duration. The method can include depositing a back contact adjacent to the semiconductor absorber layer. The method can include depositing a back support adjacent to the back contact to protect the photovoltaic device from external elements.

A photovoltaic device can include a transparent conductive oxide layer adjacent to a substrate, a semiconductor bi-layer adjacent to the transparent conductive oxide layer, and a back contact adjacent to the semiconductor bi-layer. The semiconductor bi-layer can include a semiconductor absorber layer adjacent to a semiconductor window layer. The semiconductor absorber layer can include an oriented crystallized semiconductor absorber layer. The transparent conductive oxide layer can include a cadmium stannate, an indium-doped cadmium oxide, or a tin-doped indium oxide. The substrate can include a glass, which can include a soda-lime glass.

The photovoltaic device can include a barrier layer positioned between the substrate and the transparent conductive oxide layer. The barrier layer can include a silicon dioxide or a silicon nitride.

The photovoltaic device can include a top layer adjacent to the transparent conductive oxide layer. The photovoltaic device can include both a barrier layer positioned between the substrate and the transparent conductive oxide layer, and a top layer adjacent to the transparent conductive oxide layer. The top layer can include a zinc stannate or a tin oxide. The semiconductor window layer can include a cadmium sulfide.

The oriented crystallized semiconductor absorber layer of the photovoltaic device can include an oriented cadmium telluride layer. The oriented cadmium telluride layer can have a preferred orientation. About 65% to about 75% of the crystals of the oriented cadmium telluride layer can have a preferred orientation relative to a deposition plane of the layer. The photovoltaic device can include a back support adjacent to the back contact.

A method for manufacturing a photovoltaic device can include depositing a semiconductor window layer adjacent to a transparent conductive oxide layer, and depositing an oriented semiconductor absorber layer adjacent to the semiconductor window layer.

The method can include depositing a top layer adjacent to the transparent conductive oxide layer, prior to depositing a semiconductor window layer. The transparent conductive oxide layer can include a cadmium stannate, an indium-doped cadmium oxide, or a tin-doped indium oxide. Depositing a semiconductor window layer adjacent to the transparent conductive oxide layer can include depositing a cadmium sulfide layer. Depositing a top layer adjacent to the transparent conductive oxide layer can include sputtering a zinc stannate or a tin oxide onto the transparent conductive oxide layer to form a transparent conductive oxide stack. The method can include annealing the transparent conductive oxide stack. Annealing the transparent conductive oxide stack can include heating the transparent conductive oxide stack under reduced pressure. Annealing the transparent conductive oxide stack can include heating the transparent conductive oxide stack at about 400° C. to about 800° C., or at about 500° C. to about 700° C. Annealing the transparent conductive oxide stack can include heating the transparent conductive oxide stack for about 10 to about 25 minutes, or for about 15 to about 20 minutes.

Depositing a semiconductor window layer adjacent to the transparent conductive oxide layer can include transporting a vapor. Depositing an oriented semiconductor absorber layer adjacent to the semiconductor window layer can include transporting a vapor. Depositing an oriented semiconductor absorber layer adjacent to the semiconductor window layer can include placing a cadmium telluride layer on a substrate. Depositing an oriented semiconductor absorber layer can include orienting a crystalline semiconductor absorber layer with preferred orientation. About 65% to about 75% of the crystals of the oriented semiconductor absorber layer can have a preferred orientation relative to a deposition plane of the layer.

The method can include depositing a back contact adjacent to the oriented semiconductor absorber layer. The method can include positioning a back support adjacent to the back contact.

The method can include depositing the transparent conductive oxide layer adjacent to a substrate. The method can include depositing the transparent conductive oxide layer adjacent to a barrier layer, prior to depositing the transparent conductive oxide layer adjacent to a substrate. The method can include depositing a top layer adjacent to the transparent conductive oxide layer, prior to depositing a semiconductor window layer adjacent to a transparent conductive oxide layer. The method can include depositing the transparent conductive oxide layer adjacent to a barrier layer prior to depositing the transparent conductive oxide layer adjacent to a substrate, and depositing a top layer adjacent to the transparent conductive oxide layer to form a transparent conductive oxide stack, prior to depositing a semiconductor window layer adjacent to a transparent conductive oxide layer. The method can include annealing the transparent conductive oxide stack. Annealing the transparent conductive oxide stack can include heating the transparent conductive oxide stack under reduced pressure. Annealing the transparent conductive oxide stack can include heating the transparent conductive oxide stack at about 400° C. to about 800° C., or at about 500° C. to about 700° C. Annealing the transparent conductive oxide stack can include heating the transparent conductive oxide stack for about 10 to about 25 minutes, or for about 15 to about 20 minutes.

Depositing the transparent conductive oxide layer adjacent to a substrate can include placing a cadmium stannate, an indium-doped cadmium oxide, or a tin-doped indium oxide onto the substrate. Depositing a semiconductor window layer adjacent to a transparent conductive oxide layer can include placing a cadmium sulfide layer adjacent to the transparent conductive oxide layer. Depositing the transparent conductive oxide layer adjacent to the substrate can include sputtering the transparent conductive oxide layer onto a glass to form a layered structure. The method can include annealing the layered structure. Annealing the layered structure can include heating the layered structure under reduced pressure. Annealing the layered structure can include heating the layered structure at about 400° C. to about 800° C., or at about 500° C. to about 700° C. Annealing the layered structure can include heating the layered structure for about 10 to about 25 minutes, or for about 15 to about 20 minutes.

Depositing the transparent conductive oxide layer adjacent to a barrier layer can include sputtering the transparent conductive oxide layer onto a silicon dioxide layer, or a silicon nitride layer to form a transparent conductive oxide stack. The method can include annealing the transparent conductive oxide stack. Annealing the transparent conductive oxide stack can include heating the transparent conductive oxide stack under reduced pressure. Annealing the transparent conductive oxide stack can include heating the transparent conductive oxide stack at about 400° C. to about 800° C., or at about 500° C. to about 700° C. Annealing the transparent conductive oxide stack can include heating the transparent conductive oxide stack for about 10 to about 25 minutes, or for about 15 to about 20 minutes.

Depositing a top layer adjacent to the transparent conductive oxide layer can include sputtering a zinc stannate or a tin oxide onto the transparent conductive oxide layer to form a transparent conductive oxide stack. The method can include annealing the transparent conductive oxide stack. Annealing the transparent conductive oxide stack can include heating the transparent conductive oxide stack under reduced pressure. Annealing the transparent conductive oxide stack can include heating the transparent conductive oxide stack at about 400° C. to about 800° C., or at about 500° C. to about 700° C. Annealing the transparent conductive oxide stack can include heating the transparent conductive oxide stack for about 10 to about 25 minutes, or for about 15 to about 20 minutes.

Depositing a semiconductor window layer adjacent to a transparent conductive oxide layer can include transporting a vapor. Depositing an oriented semiconductor absorber layer adjacent to the semiconductor window layer can include transporting a vapor.

Depositing an oriented semiconductor absorber layer can include placing a cadmium telluride layer on a substrate. Depositing an oriented semiconductor absorber layer can include orienting a crystalline semiconductor absorber with preferred orientation. About 65% to about 75% of the crystals of the oriented semiconductor absorber layer can have a preferred orientation relative to a deposition plane of the layer.

The method can include depositing a back contact adjacent to the oriented semiconductor absorber layer. The method can include depositing a back support adjacent to the back contact.

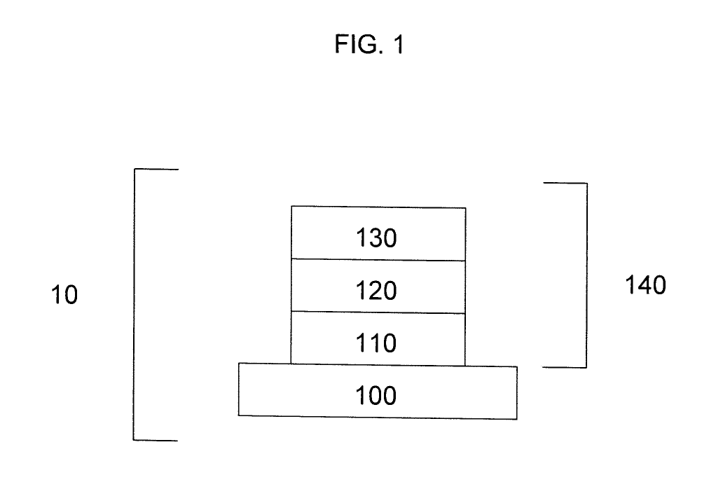

Referring to FIG. 1, a photovoltaic device 10 can include a transparent conductive oxide layer 120 deposited adjacent to a substrate 100. Transparent conductive oxide layer 120 can be deposited on substrate 100. Transparent conductive oxide layer 120 can be deposited on an intermediate layer, such as barrier layer 110. Substrate 100 can include a glass, such as soda-lime glass. Transparent conductive oxide layer 120 can be deposited by sputtering, or by any known material deposition technique. Transparent conductive oxide layer 120 can include any suitable transparent conductive oxide material, including a cadmium stannate, an indium-doped cadmium oxide, or a tin-doped indium oxide.

In continuing reference to FIG. 1, barrier layer 110 can prevent sodium from diffusing from soda-lime glass substrate 100 into transparent conductive oxide layer 120. Barrier layer 110 can be deposited through any known deposition technique, including sputtering, and can include any suitable barrier material, including a silicon dioxide or a silicon nitride. A top layer, such as buffer layer 130 can be deposited adjacent to transparent conductive oxide layer 120. Buffer layer 130 can provide a surface onto which subsequent layers can be deposited, adjacent to transparent conductive oxide layer 120. Buffer layer 130 can be deposited through any known deposition technique, including sputtering and can include any suitable material, such as zinc stannate or a tin oxide. Transparent conductive oxide layer 120 can form transparent conductive oxide stack 140. Barrier layer 110 and buffer layer 130 can be part of transparent conductive oxide stack 140.

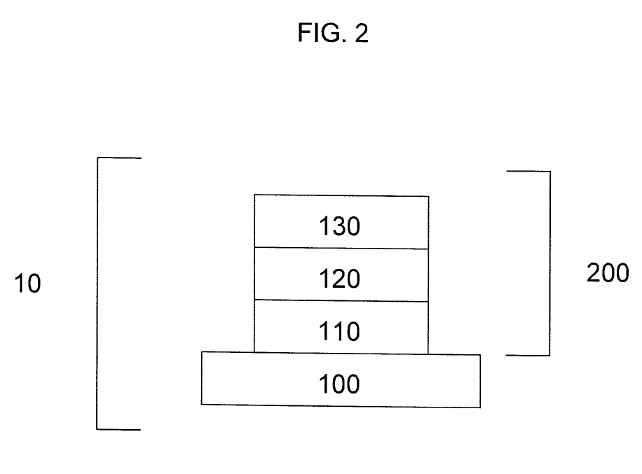

Referring to FIG. 1 and FIG. 2, transparent conductive oxide stack 140 from FIG. 1 can be annealed to form an annealed transparent conductive oxide stack 200. The annealing can occur under any suitable conditions. Transparent conductive oxide stack 140 can be annealed at any suitable pressure. Transparent conductive oxide stack 140 can be annealed under reduced pressure, a pressure less than atmospheric pressure, such as a substantial vacuum. Transparent conductive oxide stack 140 can be annealed at any suitable temperature or temperature range. For example, transparent conductive oxide stack 140 can be annealed at about 400° C. to about 800° C. Transparent conductive oxide stack 140 can be annealed at about 500° C. to about 700° C. The annealing can occur in the presence of a gas selected to control an aspect of the annealing. Transparent conductive oxide stack 140 can be annealed for any suitable duration. Transparent conductive oxide stack 140 can be annealed for about 10 to about 25 minutes. Transparent conductive oxide stack 140 can be annealed for about 15 to about 20 minutes. Annealing transparent conductive oxide stack 140 from FIG. 1 can provide annealed transparent conductive oxide stack 200 from FIG. 2.

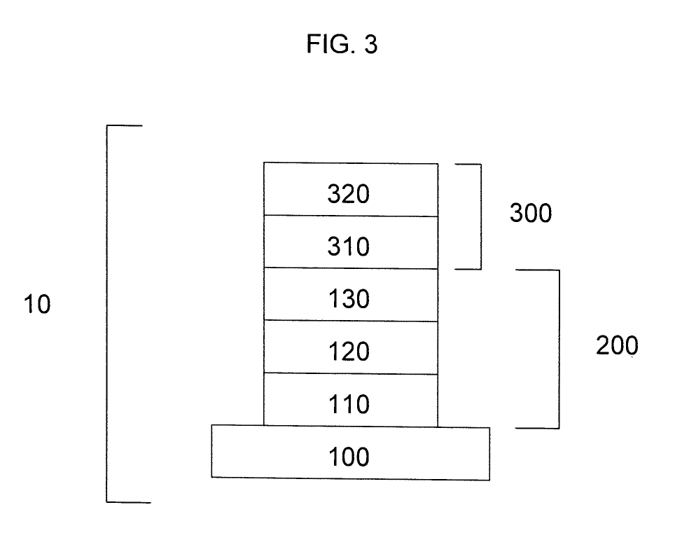

Referring to FIG. 3, semiconductor bi-layer 300 can be formed adjacent to annealed transparent conductive oxide stack 200. Semiconductor bi-layer 300 can be formed on annealed transparent conductive oxide stack 200. Semiconductor bi-layer 300 can include semiconductor window layer 310 and oriented semiconductor absorber layer 320. Semiconductor window layer 310 of semiconductor bi-layer 300 can be deposited adjacent to annealed transparent conductive oxide stack 200. Semiconductor window layer 310 can include any suitable window material, such as cadmium sulfide, and can be formed by any suitable deposition method, such as vapor transport deposition. Oriented semiconductor absorber layer 320 can be deposited adjacent to semiconductor window layer 310. Oriented semiconductor absorber layer 320 can be deposited on semiconductor window layer 310. Oriented semiconductor absorber layer 320 can be any suitable absorber material, such as cadmium telluride, and can be formed by any suitable method, such as vapor transport deposition.

Oriented semiconductor absorber layer 320 in photovoltaic device 10 can have an oriented crystalline microstructure including large grains. Oriented semiconductor absorber layer 320 can have a preferred orientation. For example, a preferred orientation semiconductor absorber layer 320 can have a preferential orientation as opposed to a random orientation, such as an in-plane orientation, an orientation perpendicular to a deposition plane of the layer, or an orientation perpendicular to the growth plane. Oriented semiconductor absorber layer 320 can have a microstructure providing crystals of oriented semiconductor absorber layer to be oriented in a deposition plane of the layer. About 65% to about 75% of the crystals of oriented semiconductor absorber layer 320 can have a preferred orientation relative to a deposition plane of the layer. The resulting crystal grains can be large. For example, the grains can have an average size of about 1.4 μm or greater. The grains can have an average size of about 1.8 μm or greater, for example 1.88 μm.

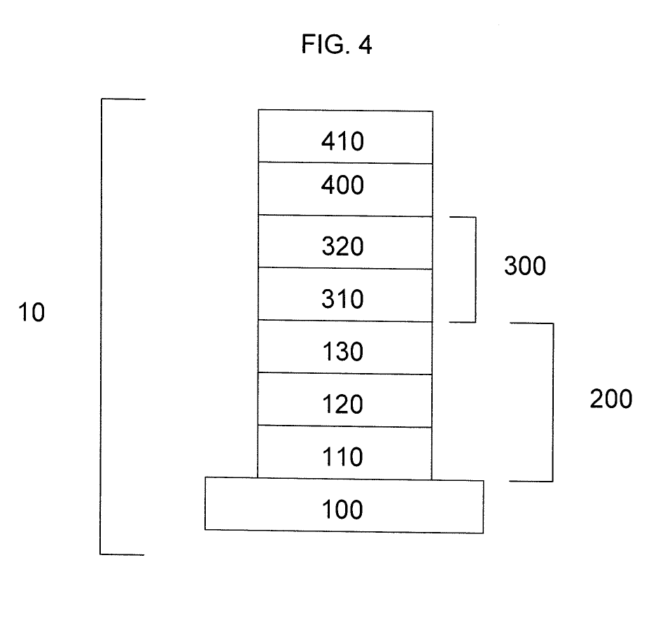

Referring to FIG. 4, a back contact 400 can be deposited adjacent to oriented semiconductor absorber layer 320. Back contact 400 can be deposited adjacent to semiconductor bi-layer 300. Back contact 400 can include any suitable material, including a metal. A back support 410 can be positioned adjacent to back contact 400.

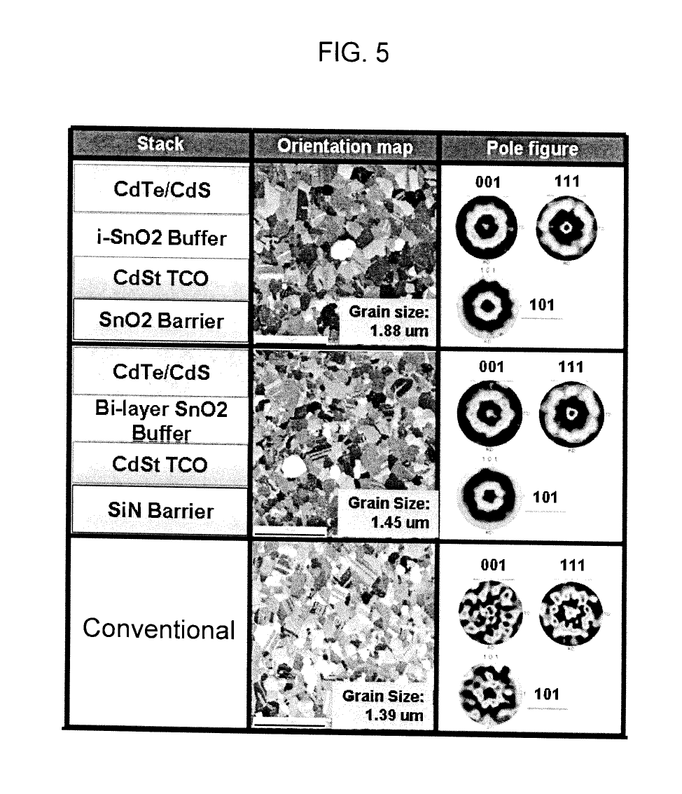

Referring to FIG. 5, two photovoltaic devices manufactured as described above were compared with a known photovoltaic device structure. The conventional device included a cadmium sulfide-cadmium telluride bi-layer formed on glass. The first experimental device included a transparent conductive oxide stack in accordance with the present invention, including a silicon nitride barrier layer, a cadmium stannate transparent conductive oxide layer, and a bi-layer tin oxide buffer layer. A cadmium sulfide-cadmium telluride bi-layer was formed on the transparent conductive oxide stack. The second experimental device included a transparent conductive oxide stack in accordance with the present invention, including a tin oxide barrier layer, a cadmium stannate transparent conductive oxide layer and a doped tin oxide buffer layer. A cadmium sulfide-cadmium telluride bi-layer was formed on the transparent conductive oxide stack.

In both experimental devices, the transparent conductive oxide stack was deposited by an in-line sputter system layer-by-layer at room temperature, and then annealed in a vacuum system at around 600° C. for about 17 minutes. The stacks were then coated with a cadmium sulfide window layer and a cadmium telluride layer absorber layer. The orientation maps of FIG. 5 show that the cadmium telluride crystals of the experimental devices had strong <111> orientation compared to those of the conventional sample, which were polycrystalline with random orientation. The orientation maps also indicate a larger grain size for the first and second experimental devices (1.88 μm and 1.45 μm respectively) than that for the conventional sample (1.39 μm). The pole figure maps of FIG. 5 show a strong orientation in the <111> direction for the experimental devices.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A photovoltaic device, comprising:
a transparent conductive oxide layer adjacent to a substrate;
a semiconductor bi-layer adjacent to the transparent conductive oxide layer, the semiconductor bi-layer comprising a semiconductor absorber layer adjacent to a semiconductor window layer, wherein the semiconductor absorber layer comprises an oriented crystallized semiconductor absorber layer; and
a back contact adjacent to the semiconductor bi-layer.

2. The photovoltaic device of claim 1, wherein the transparent conductive oxide layer comprises a cadmium stannate.

3. The photovoltaic device of claim 1, wherein the transparent conductive oxide layer comprises an indium-doped cadmium oxide.

4. The photovoltaic device of claim 1, wherein the transparent conductive oxide layer comprises a tin-doped indium oxide.

5. The photovoltaic device of claim 1, wherein the substrate comprises a glass.

6. The photovoltaic device of claim 5, wherein the glass comprises a soda-lime glass.

7. The photovoltaic device of claim 1, further comprising a barrier layer positioned between the substrate and the transparent conductive oxide layer.

8. The photovoltaic device of claim 7, wherein the barrier layer comprises a silicon dioxide.

9. The photovoltaic device of claim 7, wherein the barrier layer comprises a silicon nitride.

10. The photovoltaic device of claim 1, further comprising a top layer adjacent to the transparent conductive oxide layer.

11. The photovoltaic device of claim 10, wherein the top layer comprises a zinc stannate.

12. The photovoltaic device of claim 10, wherein the top layer comprises a tin oxide.

13. The photovoltaic device of claim 1, wherein the semiconductor window layer comprises a cadmium sulfide.

14. The photovoltaic device of claim 1, wherein the oriented crystallized semiconductor absorber layer comprises an oriented cadmium telluride layer.

15. The photovoltaic device of claim 14, wherein the oriented cadmium telluride layer has a preferred orientation.

16. The photovoltaic device of claim 15, wherein about 65% to about 75% of the crystals of the oriented cadmium telluride layer have a preferred orientation relative to a deposition plane of the layer.

17. The photovoltaic device of claim 1, further comprising a back support adjacent to the back contact.

18. A method for manufacturing a photovoltaic device, the method comprising:
depositing a semiconductor window layer adjacent to a transparent conductive oxide layer; and
depositing an oriented semiconductor absorber layer adjacent to the semiconductor window layer.

19. The method of claim 18, further comprising depositing a top layer adjacent to the transparent conductive oxide layer, prior to depositing a semiconductor window layer.

20. The method of claim 18, wherein the transparent conductive oxide layer comprises a cadmium stannate.

21. The method of claim 18, wherein the transparent conductive oxide layer comprises an indium-doped cadmium oxide.

22. The method of claim 18, wherein the transparent conductive oxide layer comprises a tin-doped indium oxide.

23. The method of claim 18, wherein depositing a semiconductor window layer adjacent to the transparent conductive oxide layer comprises placing a cadmium sulfide layer on the substrate.

24. The method of claim 19, wherein depositing a top layer adjacent to the transparent conductive oxide layer comprises sputtering a zinc stannate onto the transparent conductive oxide layer to form a transparent conductive oxide stack.

25. The method of claim 19, wherein depositing a top layer adjacent to the transparent conductive oxide layer comprises sputtering a tin oxide onto the transparent conductive oxide layer to form a transparent conductive oxide stack.

26. The method of claim 20, further comprising annealing the transparent conductive oxide stack.

27. The method of claim 26, wherein annealing the transparent conductive oxide stack comprises heating the transparent conductive oxide stack under reduced pressure.

28. The method of claim 26, wherein annealing the transparent conductive oxide stack comprises heating the transparent conductive oxide stack at about 400° C. to about 800° C.

29. The method of claim 28, wherein annealing the transparent conductive oxide stack comprises heating the transparent conductive oxide stack at about 500° C. to about 700° C.

30. The method of claim 26, wherein annealing the transparent conductive oxide stack comprises heating the transparent conductive oxide stack for about 10 to about 25 minutes.

31. The method of claim 30, wherein annealing the transparent conductive oxide stack comprises heating the transparent conductive oxide stack for about 15 minutes to about 20 minutes.

32. The method of claim 18, wherein depositing a semiconductor window layer adjacent to the transparent conductive oxide layer comprises transporting a vapor.

33. The method of claim 18, wherein depositing an oriented semiconductor absorber layer adjacent to the semiconductor window layer comprises transporting a vapor.

34. The method of claim 18, wherein depositing an oriented semiconductor absorber layer adjacent to the semiconductor window layer comprises placing a cadmium telluride layer on a substrate.

35. The method of claim 18, wherein depositing an oriented semiconductor absorber layer adjacent to the semiconductor window layer comprises orienting a crystalline semiconductor absorber layer with preferred orientation.

36. The method of claim 18, wherein about 65% to about 75% of the crystals of the oriented semiconductor absorber layer have a preferred orientation relative to a deposition plane of the layer.

37. The method of claim 18, further comprising depositing a back contact adjacent to the oriented semiconductor absorber layer.

38. The method of claim 37, further comprising positioning a back support adjacent to the back contact.

39. The method of claim 18, further comprising depositing the transparent conductive oxide layer adjacent to a substrate.

40. The method of claim 39, further comprising depositing the transparent conductive oxide layer adjacent to a barrier layer, prior to placing the transparent conductive oxide layer adjacent to a substrate.

41. The method of claim 40, further comprising depositing a top layer adjacent to the transparent conductive oxide layer to form a transparent conductive oxide stack, prior to depositing a semiconductor window layer adjacent to a transparent conductive oxide layer.

42. The method of claim 41, further comprising annealing the transparent conductive oxide stack.

43. The method of claim 39, wherein depositing the transparent conductive oxide layer adjacent to a substrate comprises placing a cadmium stannate onto the substrate.

44. The method of claim 39, wherein depositing the transparent conductive oxide layer adjacent to a substrate comprises placing an indium-doped cadmium oxide onto the substrate.

45. The method of claim 39, wherein depositing the transparent conductive oxide layer adjacent to a substrate comprises placing a tin-doped indium oxide onto the substrate.

46. The method of claim 39, wherein depositing a semiconductor window layer adjacent to a transparent conductive oxide layer comprises placing a cadmium sulfide layer adjacent to the transparent conductive oxide layer.

47. The method of claim 39, wherein depositing the transparent conductive oxide layer adjacent to a substrate comprises sputtering the transparent conductive oxide layer onto a glass to form a layered structure.

48. The method of claim 47, further comprising annealing the layered structure.

49. The method of claim 40, wherein depositing the transparent conductive oxide layer adjacent to a barrier layer comprises sputtering the transparent conductive oxide layer onto a silicon dioxide layer to form a transparent conductive oxide stack.

50. The method of claim 40, wherein depositing the transparent conductive oxide layer adjacent to a barrier layer comprises sputtering the transparent conductive oxide layer onto a silicon nitride layer to form a transparent conductive oxide stack.

51. The method of claim 41, wherein depositing a top layer adjacent to the transparent conductive oxide layer comprises sputtering a zinc stannate onto the transparent conductive oxide layer to form a transparent conductive oxide stack.

52. The method of claim 41, wherein depositing a top layer adjacent to the transparent conductive oxide layer comprises sputtering a tin oxide onto the transparent conductive oxide layer to form a transparent conductive oxide stack.

53. The method of claim 41, wherein depositing a semiconductor window layer adjacent to a transparent conductive oxide layer comprises transporting a vapor.

54. The method of claim 41, wherein depositing an oriented semiconductor absorber layer adjacent to the semiconductor window layer comprises transporting a vapor.

55. The method of claim 41, wherein depositing an oriented semiconductor absorber layer adjacent to the semiconductor window layer comprises placing a cadmium telluride layer on a substrate.

56. The method of claim 41, wherein depositing an oriented semiconductor absorber layer comprises orienting a crystalline semiconductor absorber layer with preferred orientation.

57. The method of claim 41, wherein about 65% to about 75% of the crystals of the oriented semiconductor absorber layer have a preferred orientation relative to a deposition plane of the layer.

58. The method of claim 41, further comprising depositing a back contact adjacent to the oriented semiconductor absorber layer.

59. The method of claim 58, further comprising depositing a back support adjacent to the back contact.
